(19) United States
(12) Patent Application Publication
(10) Pub. No.: US 2026/0143749 A1
(43) Pub. Date: May 21, 2026

(54) EFFECTIVE WIDTH CONTROL FOR SEMICONDUCTOR DEVICES

(71) Applicant: International Business Machines Corporation, Armonk, NY (US)

(72) Inventors: Debarghya Sarkar, Latham, NY (US); Ruilong Xie, Niskayuna, NY (US); Tao Li, Slingerlands, NY (US); Julien Frougier, Albany, NY (US)

(21) Appl. No.: 18/953,592

(22) Filed: Nov. 20, 2024

(51) Int. Cl. H01L 29/423; H01L 21/762; H01L 21/8234; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 84/0128; H10D 84/013; H10D 84/0149; H10D 84/038; H10W 10/014; H10W 10/17

(57) ABSTRACT

A semiconductor device includes a transistor comprising a first source/drain region, a second source/drain region, and a first stack of channel segments positioned between the first source/drain region and the second source/drain region, where the regions between adjacent channel segments in the first stack are filled by a high-k dielectric material. At least a portion of at least one of the channel segments in the first stack of channel segments comprises an interlayer dielectric material.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments described herein provide techniques for controlling effective width of semiconductor devices.

In one embodiment, a semiconductor device includes a transistor including a first source/drain region, a second source/drain region, and a first stack of channel segments positioned between the first source/drain region and the second source/drain region, where the regions between adjacent channel segments in the first stack are filled by a high-k dielectric material. At least a portion of at least one of the channel segments in the first stack of channel segments comprises an interlayer dielectric material.

In another embodiment, a semiconductor device includes a first transistor including a first source/drain region, a second source/drain region, and a first stack of channel segments positioned between the first source/drain region and the second source/drain region. The semiconductor device includes a second transistor comprising a third source/drain region, a fourth source/drain region, and a second stack of channel segments positioned between the third source/drain region and the fourth source/drain region, where regions between adjacent channel segments in the first stack of channel segments and the second stack of channel segments are filled by a high-k dielectric material, and where at least a portion of at least one of the channel segments in each of the first stack of channel segments and the second stack of channel segments comprises an other dielectric material corresponding to a backside interlayer dielectric layer.

In yet another embodiment, a method includes forming a transistor structure comprising a first source/drain region, a second source/drain region, and a stack of channel segments positioned between the first source/drain region and the second source/drain region and filling regions between adjacent channel segments in the stack of channel segments with a high-k dielectric material. The method includes removing at least a portion of at least one of the channel segments in the stack of channel segments and forming a work-function metal on an outer surface of the stack of channel segments. The method also includes forming a backside interlayer dielectric layer that fills in the removed portion of the at least one channel segment.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure indicating X, Y1, and Y2 cross-section locations on which the cross-sectional views of FIGS. 2-14B are based.

FIG. 2 depicts a cross-sectional view corresponding to line Y2 in FIG. 1 during an intermediate step of a method of fabricating a nanosheet transistor structure, according to an illustrative embodiment.

FIG. 3 depicts a cross-sectional view corresponding to line Y2 in FIG. 1 following nanosheet layer patterning and isolation region formation, according to an embodiment.

FIG. 4A depicts a first cross-sectional view corresponding to the line X in FIG. 1 following dummy gate formation, gate spacer formation, inner spacer formation, placeholder formation, gate hardmask (HM) formation, and source/drain region formation, according to an illustrative embodiment.

FIG. 4B depicts a second cross-sectional view corresponding to the line Y1 in FIG. 1 following the dummy gate formation, the gate spacer formation, the inner spacer formation, the placeholder formation, the gate HM formation, and the source/drain region formation, according to an illustrative embodiment.

FIG. 4C depicts a third cross-sectional view corresponding to the line Y2 in FIG. 1 following the dummy gate formation, the gate spacer formation, the inner spacer formation, the placeholder formation, the gate HM formation, and the source/drain region formation, according to an illustrative embodiment.

FIG. 5A depicts a first cross-sectional view corresponding to the line X in FIG. 1 following interlayer dielectric (ILD) layer formation and planarization, dummy gate removal, and sacrificial layer removal, according to an embodiment.

FIG. 5B depicts a second cross-sectional view corresponding to the line Y1 in FIG. 1 following the ILD layer formation and planarization, the dummy gate removal, and the sacrificial layer removal, according to an embodiment.

FIG. 5C depicts a third cross-sectional view corresponding to the line Y2 in FIG. 1 following the ILD layer formation and planarization, the dummy gate removal, and the sacrificial layer removal, according to an embodiment.

FIG. 6A depicts a first cross-sectional view corresponding to the line X in FIG. 1 following formation of a high-k dielectric layer, according to an embodiment.

FIG. 6B depicts a second cross-sectional view corresponding to the line Y1 in FIG. 1 following the formation of the high-k dielectric layer, according to an embodiment.

FIG. 6C depicts a third cross-sectional view corresponding to the line Y2 in FIG. 1 following the formation of a high-k dielectric layer, according to an embodiment.

FIG. 7A depicts a first cross-sectional view corresponding to the line X in FIG. 1 following replacement metal gate (RMG) formation, middle-of-line (MOL) contact formation, back-end-of-line (BEOL) interconnect formation, and carrier wafer bonding, according to an embodiment.

FIG. 7B depicts a second cross-sectional view corresponding to the line Y1 in FIG. 1 following the RMG formation, the MOL contact formation, the BEOL interconnect formation, and the carrier wafer bonding, according to an embodiment.

FIG. 7C depicts a third cross-sectional view corresponding to the line Y2 in FIG. 1 following the RMG formation, the MOL contact formation, the BEOL interconnect formation, and the carrier wafer bonding, according to an embodiment.

FIG. 8A depicts a first cross-sectional view corresponding to the line X in FIG. 1 following wafer flipping, semiconductor substrate removal stopping at an etch stop layer, and partial recessing of the remaining semiconductor substrate, according to an embodiment.

FIG. 8B depicts a second cross-sectional view corresponding to the line Y1 in FIG. 1 following the wafer flipping, the semiconductor substrate removal stopping at the etch stop layer, and the partial recessing of the remaining semiconductor substrate, according to an embodiment.

FIG. 8C depicts a third cross-sectional view corresponding to the line Y2 in FIG. 1 following the wafer flipping, the semiconductor substrate removal stopping at the etch stop layer, and the partial recessing of the remaining semiconductor substrate, according to an embodiment.

FIG. 9A depicts a first cross-sectional view corresponding to the line X in FIG. 1 following placeholder recessing and protective cap formation, according to an embodiment.

FIG. 9B depicts a second cross-sectional view corresponding to the line Y1 in FIG. 1 following the placeholder recessing and the protective cap formation, according to an embodiment.

FIG. 9C depicts a third cross-sectional view corresponding to the line Y2 in FIG. 1 following the placeholder recessing and the protective cap formation, according to an embodiment.

FIG. 10A depicts a first cross-sectional view corresponding to the line X in FIG. 1 following removal of the remaining semiconductor substrate, according to an embodiment.

FIG. 10B depicts a second cross-sectional view corresponding to the line Y1 in FIG. 1 following the removal of the remaining semiconductor substrate, according to an embodiment.

FIG. 10C depicts a third cross-sectional view corresponding to the line Y2 in FIG. 1 following the removal of the remaining semiconductor substrate, according to an embodiment.

FIG. 11A depicts a first cross-sectional view corresponding to the line X in FIG. 1 following selective nanosheet layer removal using an organic planarization layer (OPL), according to an embodiment.

FIG. 11B depicts a second cross-sectional view corresponding to the line Y1 in FIG. 1 following the selective nanosheet layer removal using the OPL, according to an embodiment.

FIG. 11C depicts a third cross-sectional view corresponding to the line Y2 in FIG. 1 following the selective nanosheet layer removal using the OPL, according to an embodiment.

FIG. 12A depicts a first cross-sectional view corresponding to the line X in FIG. 1 following an ashing process to remove the OPL and backside ILD layer formation, according to an embodiment.

FIG. 12B depicts a second cross-sectional view corresponding to the line Y1 in FIG. 1 following the ashing process to remove the OPL and the backside ILD layer formation, according to an embodiment.

FIG. 12C depicts a third cross-sectional view corresponding to the line Y2 in FIG. 1 following the ashing process to remove the OPL and the backside ILD layer formation, according to an embodiment.

FIG. 13A depicts a first cross-sectional view corresponding to the line X in FIG. 1 following backside contact formation and backside power delivery network (BSPDN) formation, according to an embodiment.

FIG. 13B depicts a second cross-sectional view corresponding to the line Y1 in FIG. 1 following the backside contact formation and the BSPDN formation, according to an embodiment.

FIG. 13C depicts a third cross-sectional view corresponding to the line Y2 in FIG. 1 following the backside contact formation and the BSPDN formation, according to an embodiment.

FIG. 14A depicts a cross-sectional view corresponding to the line Y1 in FIG. 1 of a semiconductor structure in accordance with a first alternative process, according to an embodiment.

FIG. 14B depicts a cross-sectional view corresponding to the line Y1 in FIG. 1 of a semiconductor structure a semiconductor structure in accordance with a second alternative process, according to an embodiment.

### DETAILED DESCRIPTION

Illustrative embodiments may be described herein in the context of illustrative methods for effective width control for semiconductor devices, along with illustrative apparatus, systems, and devices formed using such methods. However, it is to be understood that embodiments described herein are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A FET is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures, the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Nanosheet devices can be viable device options instead of FinFETs. For example, nanosheets can be used as the fin structure in a dual-gate, tri-gate or gate-all-around (GAA) FET device. CMOS scaling can be enabled by the use of stacked nanosheets, which offer superior electrostatics and higher current density per footprint area than FinFETs. A general process flow for forming a nanosheet stack involves selectively removing sacrificial layers, which may be formed of silicon germanium (SiGe), between sheets of channel material, which may be formed of silicon (Si).

Conventional GAA FETs, such as nanosheet FETs, stack multiple p-type nanowires or nanosheets on top of each other in one device, and may stack multiple n-type nanowires or nanosheets on top of each other in another device. Next generation stacked FET structures provide improved track height scaling, leading to structural gains (e.g., 30-40% for different types of devices such as logic devices, static random-access memory (SRAM) devices). In next-generation stacked FET structures, n-type, and p-type nanowires or nanosheets are stacked on each other, eliminating n-to-p separation bottlenecks, and reducing the device area footprint.

As discussed above, various techniques may be used to reduce the size of FETs, including through the use of fin-shaped channels in FinFET devices, through the use of stacked nanosheet channels formed over a semiconductor substrate, and next-generation complementary FET (CFET) devices. Although embodiments described herein are discussed in connection with nanosheet stacks, the embodiments are not necessarily limited thereto, and may apply similarly to nanowire stacks.

Effective width (W_{eff}) generally refers to the portion of the channel that becomes activated upon application of a threshold voltage. At a given active footprint, vertically stacking more nanosheet channels increases W_{eff}. Conventional techniques typically involve depositing a specific number (N) of nanosheets across a wafer, resulting in effective widths that are integer multiples of N nanosheets. Such methods fail to provide precise control over W_{eff} within the nanosheet architecture.

Some embodiments described herein enable accurate and flexible tuning of effective widths for semiconductor devices. For example, at least some embodiments include a transistor structure with active regions formed of nanosheet channels and source-drain regions on either side of the nanosheets channels. The region between the nanosheets is filled with high-k dielectric material, and a work-function metal is positioned on an outer surface of the nanosheet stack that forms a particular transistor device. In at least one of the active regions, one or more segments of the nanosheet channels are removed and replaced by interlayer dielectric (ILD) material. Such embodiments allow transistors within the same chip to have different effective widths, significantly enhancing design flexibility and optimizing device performance compared to conventional techniques.

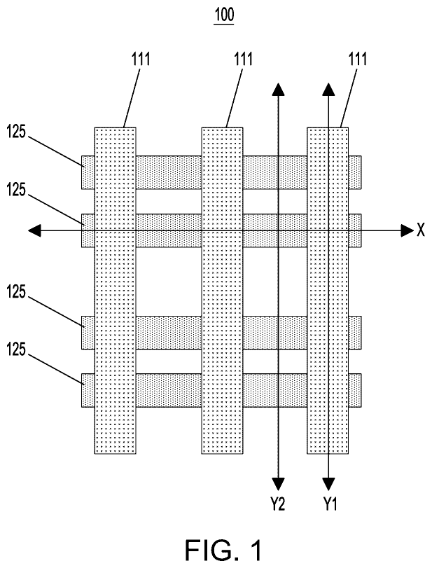

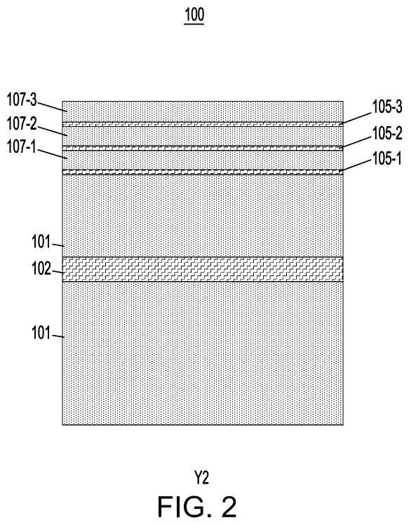

FIG. 1 depicts a top view of a semiconductor structure 100 indicating X, Y1, and Y2 cross-section locations on which the cross-sectional views of FIGS. 2-14B are based, according to an illustrative embodiment. The semiconductor structure 100 includes dummy gate portions 111 and active regions 125. The dummy gate portions 111 correspond to areas of the semiconductor structure 100 where gate structures 140 are formed, and the active regions 125 correspond to areas of the semiconductor structure 100 where source/drain regions 126 are formed, as described in more detail herein.

Referring to FIG. 1 and to the cross-sectional view in FIG. 2, which corresponds to the line Y2 in FIG. 1, the semiconductor structure 100 includes a semiconductor substrate 101 and an etch stop layer 102 formed in the semiconductor substrate 101.

The semiconductor substrate 101 may be formed of any suitable semiconductor structure, including various silicon-containing materials including, but not limited to, Si, SiGe, silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), and zinc selenide (ZnSe).

The etch stop layer 102 may comprise a buried oxide (BOX) layer or SiGe, or another suitable material such as a III-V semiconductor epitaxial layer.

The semiconductor structure 100 also includes a stacked structure of sacrificial layers 105-1, 105-2, and 105-3 (collectively “sacrificial layers 105”) and channel layers 107-1, 107-2, and 107-3 (collectively “channel layers 107”). In an illustrative embodiment, the channel layers 107 comprise silicon. In an illustrative embodiment, the sacrificial layers 105 comprise silicon germanium (SiGe) and the channel layers 107 comprise silicon. In illustrative embodiments, the sacrificial layers 105 comprise a germanium concentration of about 30% (e.g., SiGe30), but the embodiments are not necessarily limited to SiGe30 for the sacrificial layers 105.

While three sacrificial layers 105 and three channel layers 107 are shown, the embodiments are not necessarily limited to the shown number of sacrificial layers 105 and channel layers 105, and there may be more or less layers in the same alternating configuration depending on design constraints.

Although SiGe is described as a sacrificial material for sacrificial layers 105, other materials can be used as long as the sacrificial layers 105 have the property of being able to be removed selectively compared to the material of the channel layers 107.

According to one or more embodiments, the sacrificial layers 105 and channel layers 107 are epitaxially grown in an alternating and stacked configuration on the semiconductor substrate 101. For example, the sacrificial layer 105-1 is followed by channel layer 107-1 on the sacrificial layer 105-1, which is followed by the sacrificial layer 105-2 on the first channel layer 107-1, and so on. As can be understood, the sacrificial and channel layers 105 and 107 are epitaxially grown from their corresponding underlying semiconductor layers.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In a non-limiting illustrative embodiment, a height of the sacrificial layers 105 can be in the range of about 1 to 10 nm depending on the application of the device. Also, in a non-limiting illustrative embodiment, a height of the channel layers 107 can be in the range of about 1 to 10 nm depending on the desired process and application. In accordance with an embodiment, each of the channel layers 107 has the same or substantially the same composition and size as each other, and each of the sacrificial layers 105 has the same or substantially the same composition and size as each other.

As used herein, “frontside or “first side” refers to a side on top of the semiconductor substrate 101 and/or in front of, on top of or in an upward direction from the stacked gate and channel layers of the transistors in the orientation shown in the cross-sectional figures. As used herein, “backside” or “second side” refers to a side below the semiconductor substrate 101 and/or behind, below or in a downward direction from the stacked gate and channel layers of the transistors in the orientation shown in the cross-sectional figures (for example, opposite the “frontside”).

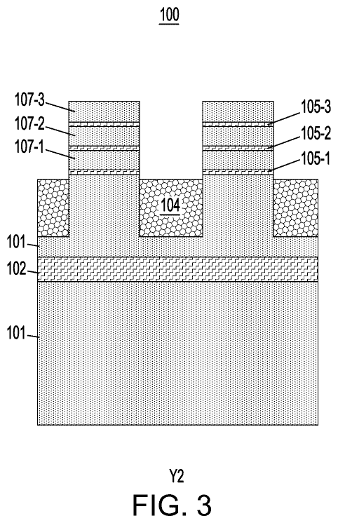

Referring to FIG. 3, portions of the nanosheet stacks comprising the sacrificial layers 105 and the channel layers 107 are removed, and portions of the semiconductor substrate 101 are recessed to a lower height. Isolation regions 104 (e.g., shallow trench isolation (STI) regions) are formed in the recessed portions of the semiconductor substrate 101 and the vacant areas left by the removal of the portions of the semiconductor substrate 101 between the remaining nanosheet stacks. The dielectric material may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma-enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

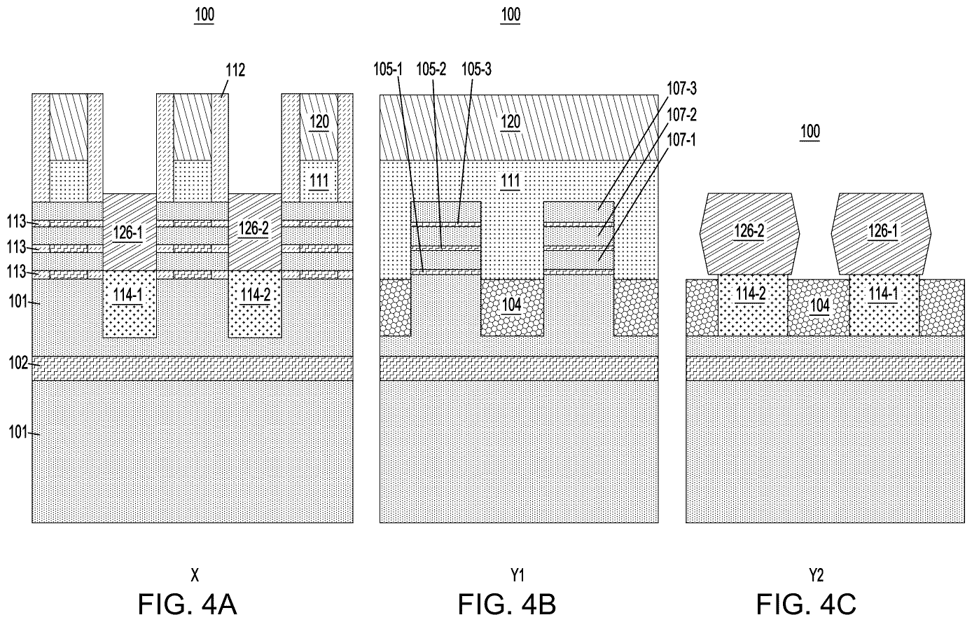

FIGS. 4A-4C show cross-sectional views, which respectively correspond to the lines X, Y1, and Y2 in FIG. 1 of the semiconductor structure 100 following formation of dummy gate portions 111, gate spacers 112, inner spacers 113, sacrificial placeholders 114-1 and 114-2 (collectively “sacrificial placeholders 114”), a gate HM layer 120, and source/drain regions 126-1 and 126-2 (collectively “source/drain regions 126”), according to an illustrative embodiment.

The dummy gate portions 111 are formed on the uppermost channel layers 107-3 and around the stacked structures of the sacrificial layers 105 and the channel layers 107. The dummy gate portions 111 include, but are not necessarily limited to, an amorphous silicon (a-Si) layer. The dummy gate portions 111 are deposited using deposition techniques such as, for example, CVD, PECVD, RFCVD, PVD, ALD, MBD, PLD, LSMCD, sputtering and/or plating, followed by a planarization process, such as chemical mechanical planarization (CMP), and lithography and etching steps to remove excess dummy gate material, and pattern the deposited layer.

A gate HM layer 120 is formed on the dummy gate portions 111. The gate HM layer 120 comprises, for example, a nitride such as SiN or other nitride material.

Gate spacers 112 are formed on sides of the gate HM layer 120 and dummy gate portions 111 by one or more of the deposition techniques noted in connection with deposition of the dummy gate material, for example. The material of the gate spacers 112 can comprise for example, one or more dielectrics, including, but not necessarily limited to, SiN, SiON, SiOC, SiCN, BN, SiBN, SiBCN, SiOCN, SiOₓ, or combinations thereof. According to an embodiment, the gate HM layer 120 and gate spacers 112 can be the same material or different materials. The gate spacers 112 can be formed by any suitable techniques such as deposition followed by directional etching. Deposition may include, but is not limited to, ALD or CVD. Directional etching may include but is not limited to, reactive ion etching (RIE).

Exposed portions of the stacked structures of the sacrificial layers 105 and the channel layers 107, which are not under the gate HM layer 120, the gate spacers 112, and the dummy gate portions 111, are removed using, for example, an etching process, such as RIE, where the gate HM layer 120, the gate spacers 112, and the dummy gate portions 111 are used as a mask. The portions of the stacked structures of the sacrificial layers 105 and the channel layers 107 under the gate HM layer 120, the gate spacers 112, and under the dummy gate portions 111 remain after the etching process, and portions of the sacrificial layers 105 and the channel layers 107 in areas that correspond to where the source/drain regions 126 will be formed are removed.

Due to, for example, germanium in the sacrificial layers 105, lateral etching of the sacrificial layers 105 can be performed selective to the channel layers 107, such that the side portions of the sacrificial layers 105 can be removed to create vacant areas to be filled in by the inner spacers 113. The material of the inner spacers 113 can comprise, but is not necessarily limited to, a nitride, such as, SiN, SiON, SiCN, BN, SiBN, SiBCN or SiOCN. Like the gate spacers 112, the inner spacers 113 can be formed by any suitable techniques such as deposition followed by directional etching.

Exposed portions of the semiconductor substrate 101 between the stacked structures of the sacrificial layers 105 and the channel layers 107 and between the isolation regions 104 are removed and filled with sacrificial materials to form sacrificial placeholders 114. The source/drain regions 126 are formed. In illustrative embodiments, the sacrificial placeholders 114 can comprise, for example, SiGe, III-V semiconductor material or other semiconductor material. The sacrificial placeholders 114 and the source/drain regions 126 can be epitaxially grown in a bottom-up epitaxial growth process. For example, the sacrificial placeholders 114 can be grown from the exposed portions of the semiconductor substrate 101, and the source/drain regions 126 can be epitaxially grown from the exposed surfaces of their corresponding sacrificial placeholders 114.

As can be seen, the bottom portions of the sacrificial placeholders 114 are disposed in and fill the trenches resulting from the recessing of the semiconductor substrate 101, and the bottom portions of the source/drain regions 126 are positioned above the sacrificial placeholders 114 and between the stacked structure of the sacrificial layers 105 and the channel layers 107. The isolation regions 104 are disposed around one or more sides of the sacrificial placeholders 114. Side surfaces of respective ones of the channel layers 107 contact a side surface of at least one of the source/drain regions 126.

In the case of n-type FETS (nFETs), the source/drain regions 126 can comprise silicon doped with n-type dopants including, for example, phosphorus (P), arsenic (As) and antimony (Sb). In the case of p-type FETS (pFETs), the source/drain regions 126 can comprise silicon doped with n-type dopants including, for example, boron (B), boron fluoride (BF₂), gallium (Ga), indium (In), and thallium (Tl).

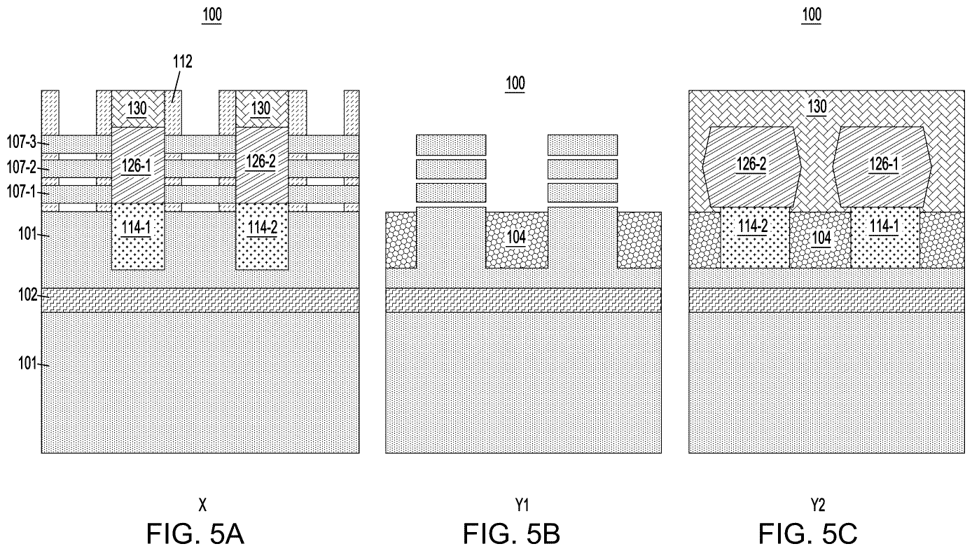

FIGS. 5A-5C show cross-sectional views, which respectively correspond to the lines X, Y1, and Y2 in FIG. 1, of the semiconductor structure 100 following formation of an ILD layer 130 formation and a planarization process, and removal of the dummy gate portions 111 and sacrificial layers 105, according to an embodiment.

The ILD layer 130 is deposited to fill in portions on and around the source/drain regions 126. The ILD layer 130 is deposited using deposition techniques such as, for example, CVD, PECVD, RFCVD, PVD, ALD, MBD, PLD, and/or LSMCD, followed by a planarization process, such as, CMP to remove excess portions of the ILD layer 130 deposited on top of the gate HM layer 120 and gate spacers 112, and to remove the gate HM layer 120 and portions of the gate spacers 112 to expose the dummy gate portions 111. The ILD layer 130 may comprise, for example, SiOx, SiOC, SiOCN or some other dielectric.

The dummy gate portions 111 and the sacrificial layers 105 are selectively removed. For example, the dummy gate portions 111 can be selectively removed using hot ammonia to remove a-Si, and the sacrificial layers 105 can be selectively removed with respect to the channel layers 107 using, for example, a dry HCl etch. Following removal of the dummy gate portions 111 and the sacrificial layers 105, the channel layers 107 are suspended.

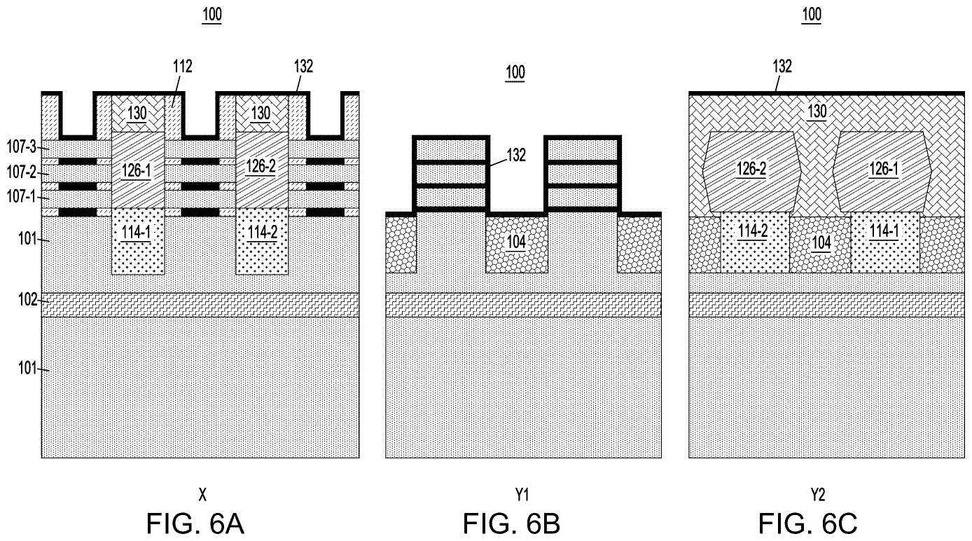

FIGS. 6A-6C show cross-sectional views, which respectively correspond to the lines X, Y1, and Y2 in FIG. 1, of the semiconductor structure 100 following formation a high-k dielectric layer 132, according to an embodiment. The high-k dielectric layer 132 is formed around the channel layers 107, thereby encasing the channel layers 107. The high-k dielectric layer 132 also covers the exposed surfaces of the isolation regions 104, the gate spacers 112, the inner spacers 113, and the ILD layer 130. In some embodiments, the high-k dielectric layer 132 includes, but is not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate.

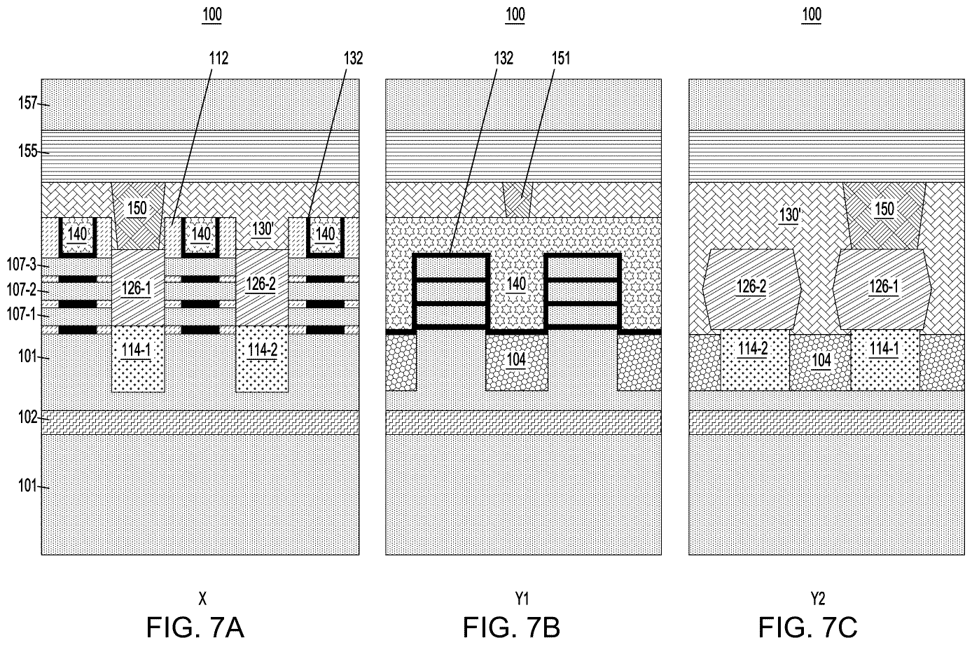

FIGS. 7A-7C show cross-sectional views, which respectively correspond to the lines X, Y1, and Y2 in FIG. 1, of the semiconductor structure 100 following formation of gate structures 140, frontside source/drain contact 150, gate contact 151, and frontside BEOL interconnects 155, and following carrier wafer bonding.

Following the formation of the high-k dielectric layer 132, the gate structures 140 are formed in the vacant portions left by removal of the dummy gate portions 111 and the sacrificial layers 105. According to an embodiment, the gate structures 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the high-k dielectric layer 132. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the high-k dielectric layer 132. It should be appreciated that various other materials may be used for the metal gate portions as desired.

A planarization process, such as CMP, can be performed to remove excess material of the gate structures 140 and the high-k dielectric layer 132 from the top surfaces of the ILD layer 130 and the gate spacers 112. Additional ILD material is deposited on top of the ILD layer 130, thereby forming ILD layer 130′.

At least one frontside source/drain contact 150 is formed in the ILD layer 130′ to contact the source/drain region 126-1. In forming the frontside source/drain contact 150, an opening is formed through portions of the ILD layer 130′. The opening exposes a portion of the source/drain region 126-1 on which the frontside source/drain contact 150 is to be formed. According to an embodiment, masks are formed on parts of the ILD layer 130′, and exposed portions of the ILD layer 130′ corresponding to where the opening is to be formed is removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers are deposited in the opening to form the frontside source/drain contacts 150. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the ILD layer 130′.

The frontside source/drain contact 150 contacts the source/drain region 126-1. The frontside source/drain contact 150 extends through the ILD layer 130′ to land on and contact the source/drain region 126-1.

The gate contact 151 is formed through the ILD layer 130′ to land on and contact a corresponding gate structure 140. The process and materials used for forming the gate contact 151 are similar to those used for forming the frontside source/drain contact 150.

The frontside BEOL interconnects 155 are formed on the ILD layer 130′ including the frontside source/drain contact 150 and gate contact 151. A carrier wafer 157 is bonded to the frontside BEOL interconnects 155. The frontside BEOL interconnects 155 include various BEOL interconnect structures which may electrically connect to the frontside source/drain contact 150 and gate contact 151. The carrier wafer 157 may be formed of materials similar to that of the semiconductor substrate 101 and may be formed over the frontside BEOL interconnects 155 using a wafer bonding process, such as dielectric-to-dielectric bonding.

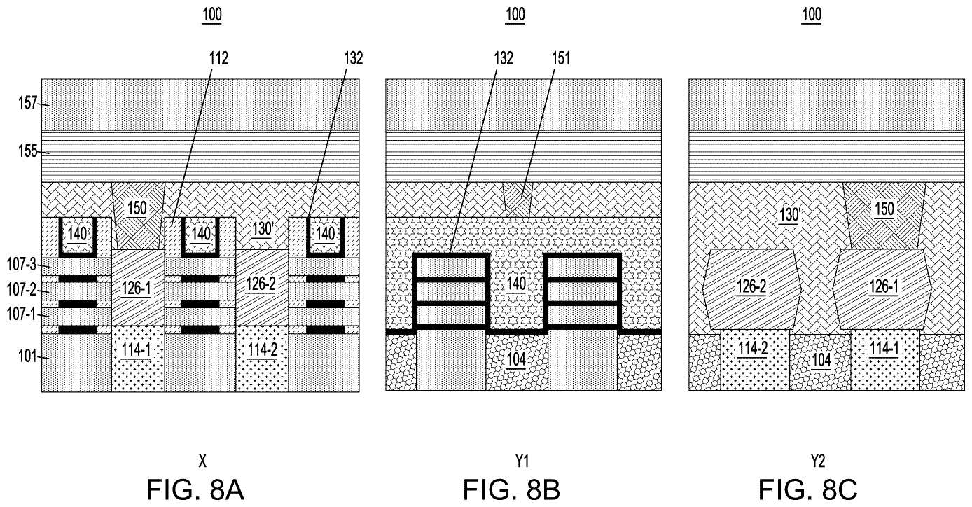

FIGS. 8A-8C show cross-sectional views, which respectively correspond to the lines X, Y1, and Y2 in FIG. 1, of the semiconductor structure 100 following wafer flipping, removal of the semiconductor substrate 101 stopping at the etch stop layer 102, and partial recessing of the remaining semiconductor substrate 101. Using the carrier wafer 157, the semiconductor structure 100 may be “flipped” (for example, rotated 180 degrees) so that it is inverted.

Additionally, the semiconductor substrate 101 is removed from the backside of the semiconductor structure 100 stopping at the etch stop layer 102. For example, the semiconductor substrate 101 can be selectively etched with an etchant that selectively etches silicon relative to a material of the etch stop layer 102. The etch stop layer 102 is also removed. The etching processes for removal of the etch stop layer 102 include, but are not limited to, IBE using Ar/CHF3 based chemistry. The semiconductor substrate 101 is then recessed up to a level corresponding to the bottom surfaces of the isolation regions 104 and the sacrificial placeholders 114 using, for example, a planarization process (e.g., CMP).

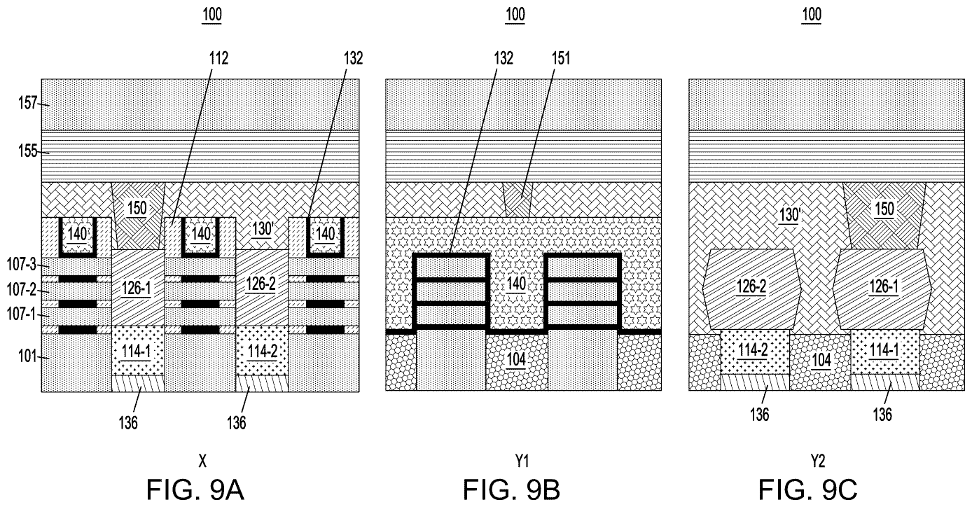

FIGS. 9A-9C show cross-sectional views, which respectively correspond to the lines X, Y1, and Y2 in FIG. 1, of the semiconductor structure 100 following partial recessing of the sacrificial placeholders 114 and formation of a protective cap layer 136, according to an embodiment. The sacrificial placeholders 114 can be recessed using, for example, selective dry and/or wet etch processes. The protective cap layer 136 is formed to fill in the portions of the sacrificial placeholders 114 that were removed. The protective cap layer 136 can comprise silicon nitride or some other suitable capping layer material.

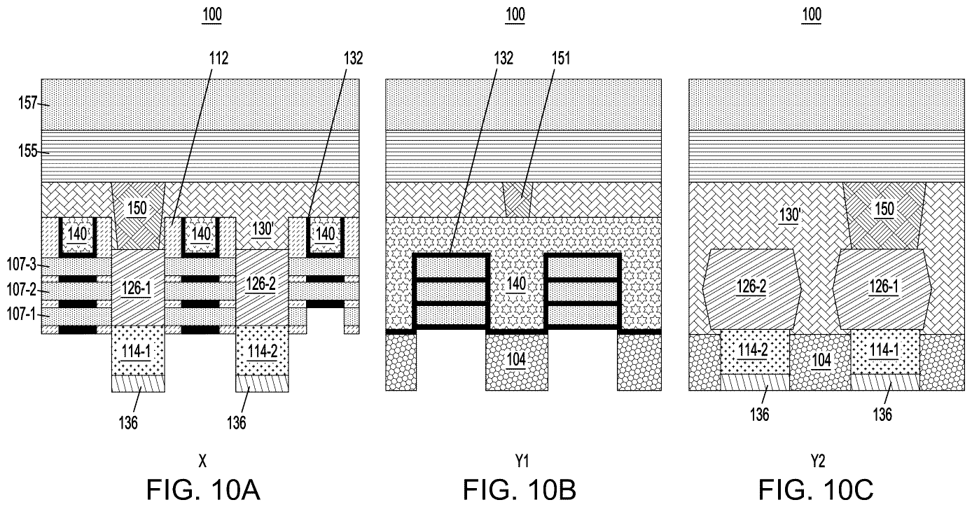

FIGS. 10A-10C show cross-sectional views, which respectively correspond to the lines X, Y1, and Y2 in FIG. 1, of the semiconductor structure 100 following removal of the remaining semiconductor substrate 101, according to an embodiment. The remaining semiconductor substrate 101 can be removed using, for example, potassium hydroxide (KOH) and TMAH.

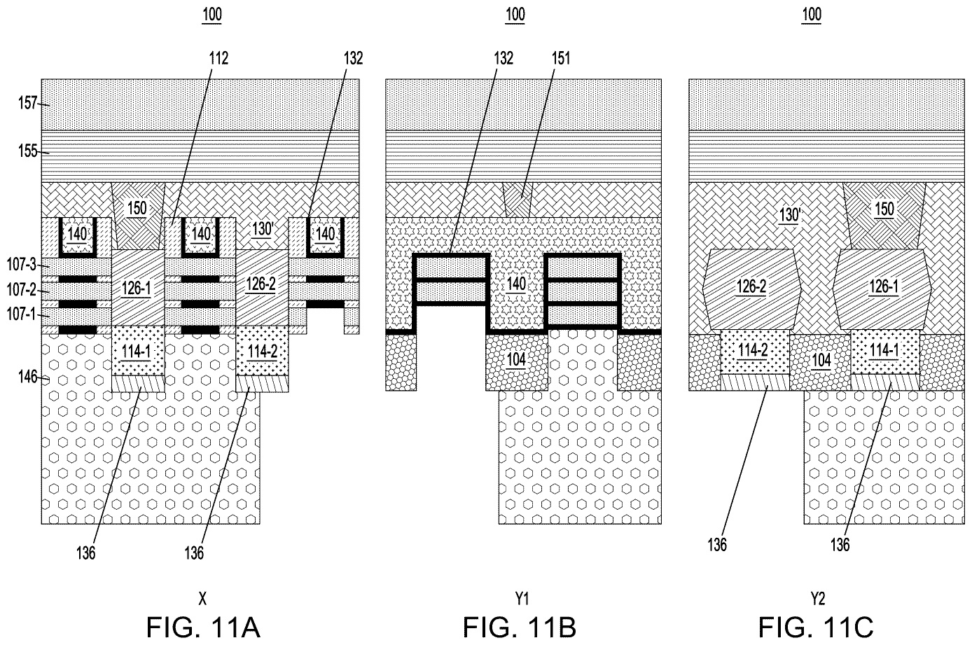

FIGS. 11A-11C show cross-sectional views, which respectively correspond to the lines X, Y1, and Y2 in FIG. 1, of the semiconductor structure 100 following removal of a segment of channel layer 107-1 using an OPL 146, according to an embodiment. The OPL 146 can be deposited on the bottom surface of the semiconductor structure 100. In some embodiments, the OPL 146 can be formed of an organic polymer such as carbon, hydrogen, and/or nitrogen, for example. The OPL 146 is then patterned to expose the portions of the high-k dielectric layer 132 that are below the segment of the channel layer 107-1 that is to be removed. A first etching process is performed to selectively remove the exposed portions of the high-k dielectric layer 132, followed by a second etching process to selectively remove the segment of the channel layer 107-1, as shown in FIGS. 11A and 11B. The etching processes used to remove the portions of the high-k dielectric layer 132 and the segment of the channel layer 107-1 can include a dry etching process (such as RIE or IBE), a wet chemical etching process, or a combination of these etching processes.

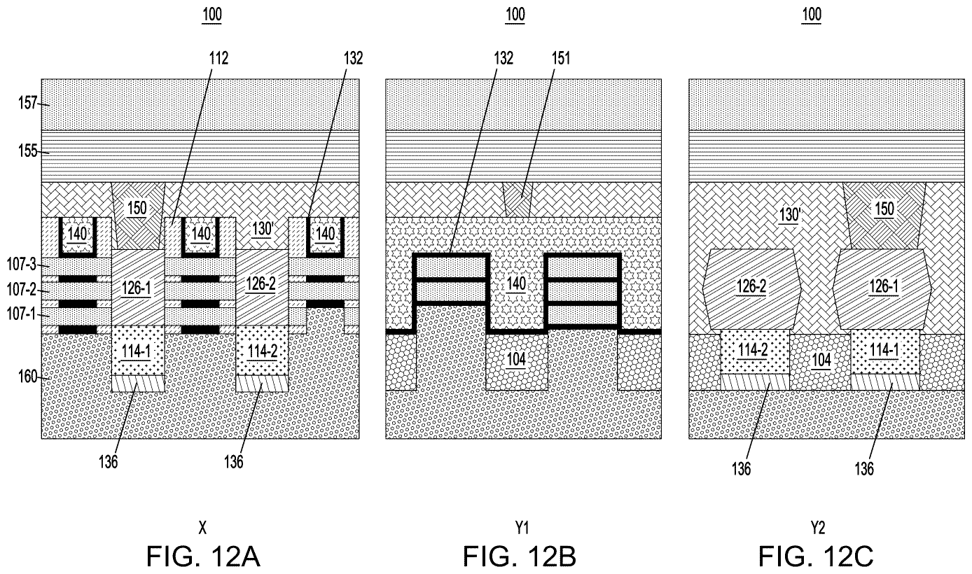

FIGS. 12A-12C show cross-sectional views, which respectively correspond to the lines X, Y1, and Y2 in FIG. 1, of the semiconductor structure 100 following an ashing process to remove the OPL 146 and formation of a backside ILD layer 160, according to an embodiment. The ashing process strips the OPL 146 using, for example, oxygen plasma, nitrogen/hydrogen plasma or other carbon strip process. Following the removal of the OPL 146, the backside ILD layer 160 is formed using deposition techniques such as CVD, PECVD, RFCVD, PVD, ALD, MBD, PLD, and/or LSMCD. The backside ILD layer 160 may comprise, for example, SiOₓ, SiOC, SiOCN or some other dielectric.

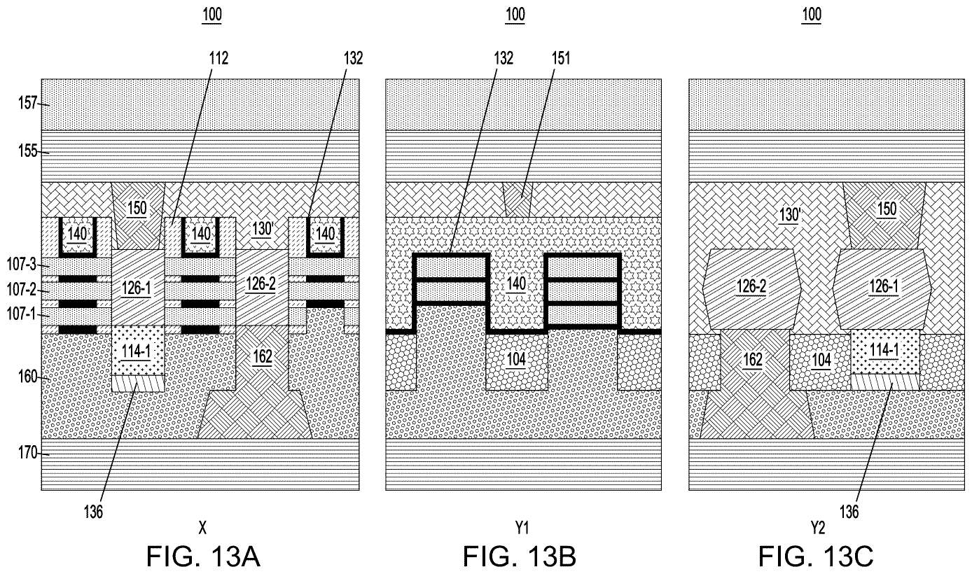

FIGS. 13A-13C show cross-sectional views, which respectively correspond to the lines X, Y1, and Y2 in FIG. 1, of the semiconductor structure 100 following formation of a backside source/drain contact 162 and BSPDN layers 170, according to an embodiment. In forming the backside source/drain contact 162, an opening is formed through a portion of the backside ILD layer 160. The opening exposes the protective cap layer 136 below the source/drain region 126-2. According to an embodiment, one or more masks are formed on parts of the backside ILD layer 160, and exposed portions of the backside ILD layer 160 corresponding to where the opening is to be formed are removed. The exposed portion of the protective cap layer 136 and the sacrificial placeholder 114-2 are then removed to expose the bottom surface of the source/drain region 126-2. The portions of the backside ILD layer 160, the protective cap layer 136, and the sacrificial placeholder 114-2 can each be removed using one or more etching processes such as wet and/or dry etching processes.

The backside source/drain contact 162 is formed by filling and planarizing of contact material. The contact material of the backside source/drain contact 162 may be similar to that of the frontside source/drain contact 150 and/or the gate contact 151, for example. The backside source/drain contact 162 contacts a backside of the source/drain region 126-2.

The BSPDN layers 170 can comprise one or more layers formed on the backside ILD layer 160 and on the backside source/drain contact 162. The BSPDN layers 170 can include various backside interconnect structures, such as power delivery network structures including, but not limited to, interconnects in a power supply path from voltage regulator modules (VRMs) to circuits. The interconnect structures can comprise, for example, power and ground planes in circuit boards, cables, connectors, and capacitors associated with a power supply. Backside power delivery prevents BEOL routing congestion, resulting in improved power performance benefits. In some embodiments, the BSPDN layers 170 can alternatively or additionally be used for signal routing, including power and/or clock signals as non-limiting examples.

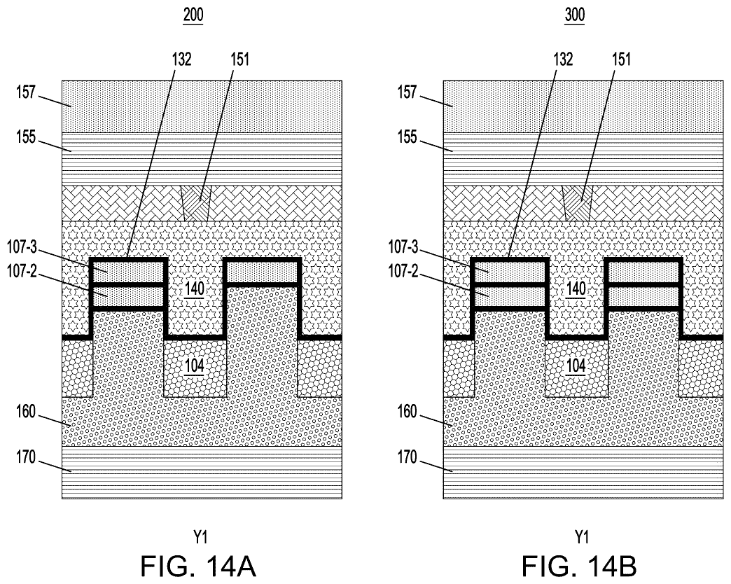

FIG. 14A depicts a cross-sectional view corresponding to the line Y1 in FIG. 1 of a semiconductor structure 200 in accordance with a first alternative process. The semiconductor structure 200 is formed using similar processes and materials as described in conjunction with FIGS. 1-13C for forming semiconductor structure 100, however, additional segments of the channel layers 107 are removed. In particular, a segment of channel layer 107-1 and a segment of channel layer 107-2 that are associated with the source/drain region 126-1 are removed using similar techniques as described in conjunction with FIGS. 11A-11C. As can be seen in FIG. 14A, the semiconductor structure 200 includes three remaining segments of the channel layers 107.

FIG. 14B depicts a cross-sectional view corresponding to the line Y1 in FIG. 1 of a semiconductor structure 300 in accordance with a second alternative process, according to an embodiment. The semiconductor structure 300 is formed using similar processes and materials as described in conjunction with FIGS. 1-13C for forming semiconductor structure 100, however, an additional segment of the channel layer 107-1 is removed. In particular, the segment of channel layer 107-1 corresponding to the source/drain region 126-1 is removed using similar techniques as described in conjunction with FIGS. 11A-11C. As can be seen in FIG. 14B, the semiconductor structure 300 includes four remaining segments of the channel layers 107.

Semiconductor devices and methods for forming the same in accordance with the above-described techniques can be employed in various applications, hardware, and/or electronic systems. Suitable hardware and systems for implementing embodiments described herein may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments. Given the teachings provided herein, one of ordinary skill in the art will be able to contemplate other implementations and applications of embodiments described herein.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

In an illustrative embodiment, a semiconductor device includes a transistor comprising a first source/drain region, a second source/drain region, and a first stack of channel segments positioned between the first source/drain region and the second source/drain region, where the regions between adjacent channel segments in the first stack are filled by a high-k dielectric material. At least a portion of at least one of the channel segments in the first stack of channel segments comprises an interlayer dielectric material.

In embodiments, the high-k dielectric material surrounds an outer surface of the first stack of channel segments.

In embodiments, the semiconductor device may include a work-function metal layer surrounding an outer surface of the high-k dielectric material.

In embodiments, the transistor further include a second stack of channel segments, where the first source/drain region is positioned between the first stack of channel segments and the second stack of channel segments.

In embodiments, at least a portion of at least one of the channel segments in the second stack may include the interlayer dielectric material.

In embodiments, a same number of channel segments in the first stack of channel segments and in the second stack of channel segments may include the interlayer dielectric material.

In embodiments, a different number of channel segments in the first stack of channel segments and in the second stack of channel segments may include the interlayer dielectric material.

In embodiments, none of the channel segments in the second stack may include the interlayer dielectric material.

In embodiments, the semiconductor device may include a shallow trench isolation region positioned between the transistor and another transistor of the semiconductor device.

In embodiments, the semiconductor device may include a backside contact placeholder comprising a dielectric cap layer, where the backside contact placeholder is positioned below one of the first source/drain region and the second source/drain region.

In another embodiment, a semiconductor device includes a first transistor including a first source/drain region, a second source/drain region, and a first stack of channel segments positioned between the first source/drain region and the second source/drain region. The semiconductor device includes a second transistor comprising a third source/drain region, a fourth source/drain region, and a second stack of channel segments positioned between the third source/drain region and the fourth source/drain region, where regions between adjacent channel segments in the first stack of channel segments and the second stack of channel segments are filled by a high-k dielectric material, and where at least a portion of at least one of the channel segments in each of the first stack of channel segments and the second stack of channel segments comprises an other dielectric material corresponding to a backside interlayer dielectric layer.

In embodiments, the semiconductor device may include a first work-function metal layer surrounding the first stack of channel segments and a second work-function metal layer surrounding the second stack of channel segments.

In embodiments, the first transistor further may include a third stack of channel segments, where the first source/drain region is positioned between the first stack of channel segments and the third stack of channel segments.

In embodiments, a same number of channel segments in the first stack of channel segments and in the third stack of channel segments may include the other dielectric material.

In embodiments, a different number of channel segments in the first stack of channel segments and in the third stack of channel segments may include the other dielectric material.

In embodiments, the semiconductor device may include at least one shallow trench isolation positioned between the first transistor and the second transistor, but not between the first source/drain region and the second source/drain region.

In embodiments, the semiconductor device may include a backside contact placeholder comprising a dielectric cap layer, where the backside contact placeholder is positioned below one of the first source/drain region and the second source/drain region.

In yet another embodiment, a method includes forming a transistor structure comprising a first source/drain region, a second source/drain region, and a stack of channel segments positioned between the first source/drain region and the second source/drain region and filling regions between adjacent channel segments in the stack of channel segments with a high-k dielectric material. The method includes removing at least a portion of at least one of the channel segments in the stack of channel segments and forming a work-function metal on an outer surface of the stack of channel segments. The method also includes forming a backside interlayer dielectric layer that fills in the removed portion of the at least one channel segment.

In embodiments, the method may further include forming a backside contact for connecting the first source/drain region to at least one backside interconnect structure.

In embodiments, the method may further include forming at least one backside contact placeholder below at least one of the first source/drain region and the second source/drain region and forming at least one dielectric cap layer below the at least one backside contact placeholder.

Conventional techniques for designing and fabricating semiconductor devices often fail to effectively control the effective width (W_{eff}) of nanosheet channels in transistor architectures, which limits design flexibility and the ability to optimize device performance. Without in any way limiting the scope, interpretation, or application of the claims appearing below, a technical effect of one or more of the example embodiments disclosed herein is improving design flexibility and performance in transistor architectures by providing precise control over the effective width. For example, at least some embodiments allow specific segments of nanosheet channels within a stack to be selectively removed and replaced with ILD material, thereby allowing accurate finetuning of the effective width.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments described herein have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a transistor comprising a first source/drain region, a second source/drain region, and a first stack of channel segments positioned between the first source/drain region and the second source/drain region;
wherein regions between adjacent channel segments in the first stack of channel segments are filled by a high-k dielectric material, and wherein at least a portion of at least one of the channel segments in the first stack of channel segments comprises an interlayer dielectric material.

2. The semiconductor device of claim 1, wherein the high-k dielectric material surrounds an outer surface of the first stack of channel segments.

3. The semiconductor device of claim 2, further comprising:
a work-function metal layer surrounding an outer surface of the high-k dielectric material.

4. The semiconductor device of claim 1, wherein the transistor further comprises:
a second stack of channel segments, wherein the first source/drain region is positioned between the first stack of channel segments and the second stack of channel segments.

5. The semiconductor device of claim 4, wherein at least a portion of at least one of the channel segments in the second stack comprises the interlayer dielectric material.

6. The semiconductor device of claim 5, wherein a same number of channel segments in the first stack of channel segments and in the second stack of channel segments comprises the interlayer dielectric material.

7. The semiconductor device of claim 5, wherein a different number of channel segments in the first stack of channel segments and in the second stack of channel segments comprise the interlayer dielectric material.

8. The semiconductor device of claim 4, wherein none of the channel segments in the second stack comprise the interlayer dielectric material.

9. The semiconductor device of claim 1, further comprising:
a shallow trench isolation region positioned between the transistor and another transistor of the semiconductor device.

10. The semiconductor device of claim 1, further comprising:
a backside contact placeholder comprising a dielectric cap layer, wherein the backside contact placeholder is positioned below one of the first source/drain region and the second source/drain region.

11. A semiconductor device comprising:
a first transistor comprising a first source/drain region, a second source/drain region, and a first stack of channel segments positioned between the first source/drain region and the second source/drain region; and
a second transistor comprising a third source/drain region, a fourth source/drain region, and a second stack of channel segments positioned between the third source/drain region and the fourth source/drain region;
wherein regions between adjacent channel segments in the first stack of channel segments and the second stack of channel segments are filled by a high-k dielectric material, and wherein at least a portion of at least one of the channel segments in each of the first stack of channel segments and the second stack of channel segments comprises an other dielectric material corresponding to a backside interlayer dielectric layer.

12. The semiconductor device of claim 11, further comprising:
a first work-function metal layer surrounding the first stack of channel segments; and
a second work-function metal layer surrounding the second stack of channel segments.

13. The semiconductor device of claim 12, wherein the first transistor further comprises a third stack of channel segments, wherein the first source/drain region is positioned between the first stack of channel segments and the third stack of channel segments.

14. The semiconductor device of claim 13, wherein a same number of channel segments in the first stack of channel segments and in the third stack of channel segments comprise the other dielectric material.

15. The semiconductor device of claim 13, wherein a different number of channel segments in the first stack of channel segments and in the third stack of channel segments comprise the other dielectric material.

16. The semiconductor device of claim 15, further comprising:
at least one shallow trench isolation positioned between the first transistor and the second transistor, but not between the first source/drain region and the second source/drain region.

17. The semiconductor device of claim 15, further comprising:
a backside contact placeholder comprising a dielectric cap layer, wherein the backside contact placeholder is positioned below one of the first source/drain region and the second source/drain region.

18. A method comprising:
forming a transistor structure comprising a first source/drain region, a second source/drain region, and a stack of channel segments positioned between the first source/drain region and the second source/drain region;
filling regions between adjacent channel segments in the stack of channel segments with a high-k dielectric material;
removing at least a portion of at least one of the channel segments in the stack of channel segments;
forming a work-function metal on an outer surface of the stack of channel segments; and
forming a backside interlayer dielectric layer that fills in the removed portion of the at least one channel segment.

19. The method of claim 18, further comprising:
forming a backside contact for connecting the first source/drain region to at least one backside interconnect structure.

20. The method of claim 18, further comprising:
forming at least one backside contact placeholder below at least one of the first source/drain region and the second source/drain region; and
forming at least one dielectric cap layer below the at least one backside contact placeholder.
